(19) United States
(12) Patent Application Publication
(10) Pub. No.: US 2026/0107773 A1
(43) Pub. Date: Apr. 16, 2026

(54) SEMICONDUCTOR PACKAGE COMPRISING A FASTENING DEVICE FOR FAS-TENING THE SEMICONDUCTOR PACKAGE TO A HEAT SINK

(71) Applicant: Infineon Technologies AG, Neubiberg (DE)

(72) Inventors: Marco LUDWIG, Wickede/Ruhr (DE); Roman Lennart TSCHIRBS, Soest (DE)

(73) Assignee: Infineon Technologies AG, Neubiberg (DE)

(21) Appl. No.: 19/350,494

(22) Filed: Oct. 6, 2025

(30) Foreign Application Priority Data
Oct. 11, 2024 (DE) 102024129427.2

(51) Int. Cl. H01L 23/40; H01L 21/50

(52) U.S. Cl. CPC H10W 40/641; H10W 95/00

(57) ABSTRACT

A semiconductor package comprises a semiconductor transistor die, an encapsulant embedding the semiconductor transistor die, and two fastening devices for fastening the semiconductor package to a heat sink, each one of the fastening devices comprising an upper portion which is partly embedded in the encapsulant, and a lower portion connected with the horizontal holding portion.

### TECHNICAL FIELD

This application claims priority under 35 U.S.C. § 119(b) to German patent application 102024129427.2, filed on Oct. 11, 2024.

The present disclosure is related to a semiconductor package comprising a fastening device for fastening the semiconductor package to a heat sink.

### BACKGROUND

Semiconductor packages are known which comprise a semiconductor die at least partially surrounded by a housing. A printed circuit board (PCB) may be mounted on the semiconductor package, and the semiconductor package may include outwardly extending fastening portions beneath the PCB. In order to attach the semiconductor package to a heat sink, the heat sink may comprise threaded holes. A screw may be inserted through the fastening portions and the threaded holes, thereby fixing the lower surface of the package to the heat sink. A through hole in the PCB is further necessary to be able to fix the screw in the threaded hole with an appropriate tool (e.g., a screwdriver).

On the customer side, the heatsink and the PCB must have different design features to enable a reliable screw fixation in their production. The heatsink needs at least two threaded holes per power module, and the PCB must have through holes corresponding to each screw location for fixing the screws in the assembly process. The implementation of the design features costs money, and is disadvantageous for several reasons. A special heatsink design is necessary including two threads with a minimum depth. The fixation of the screws is mechanically not optimal and can lead to a tilt of the module because it is difficult to fix the screws simultaneously. Moreover, the sequential order for the screw fixation is time consuming.

For these and other reasons there is a need for the present disclosure.

### SUMMARY

An aspect of the present disclosure is related to a semiconductor package comprising a semiconductor transistor die, a housing at least partially surrounding the semiconductor transistor die, and at least two fastening devices for fastening the semiconductor package to a heat sink, each one of the fastening devices comprising an upper portion which is fixed to the housing and which includes a resilient region, and a lower portion connected with the resilient region.

According to an embodiment of the semiconductor package, the lower portion is designed to function as a claw, namely by forming an external end of the lower portion so that it can hook onto the inner wall of a bore in the heat sink. For example, the lower portion may comprise a vertical shaft and a spring attached to the vertical shaft at its external end, which spring is bent upwards so that during insertion into a bore of the heatsink it can hook with its external end on an inner wall of the bore. The vertical shaft and the spring can be fabricated from stainless steel.

According to another example, an external end of the lower portion may comprise a vertical shaft which has the form of an expansion dowel. The lateral protruding portions of the dowel can also hook on an inner wall of the bore.

In addition to the above, the resilient regions of the upper portion provide a restoring force when the lower portion is inserted into the bore of the heat sink. At the end of the process of inserting the lower portion into the bore, this restoring force causes a force onto the lower portion directed upwards, which causes the external lower part of the lower portion to wedge into the inner wall of the bore. This restoring force also serves to press a lower thermally conductive surface of the package into contact with the heat sink to facilitate heat transfer from the package to the heat sink.

According to an embodiment of the semiconductor package, the two fastening devices are embedded in two opposing side walls of the housing.

The present disclosure thus describes a metallic component which is moulded to a housing of a power module, providing an elastic structure for the press down force. The fastening device provides sharp metal claws which can be fixed into the metallic blind hole just by a linear press-in movement.

According to an embodiment of the semiconductor package, the semiconductor package is further configured to have a printed circuit board connected thereto. According to an example thereof, the printed circuit board comprises two through-holes which are, when the printed circuit board is mounted to the housing, configured to be arranged directly above central sections of the horizontal portions and the vertical portions of the fastening devices.

According to an embodiment of the semiconductor package, the semiconductor package further comprises a substrate, the semiconductor transistor die being attached to the substrate, wherein the substrate can be one or more of a direct copper bond, a direct aluminum bond, an aluminum metal braze, or an insulated metal substrate.

The semiconductor package may further comprise a thermally conductive lower layer for effectively transferring heat from the package to the heat sink. This layer may take the form of a metallic layer, in particular made of copper, covering a lowermost main surface of the semiconductor package, and the metallic layer may form part of the substrate.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description.

The elements of the drawings are not necessarily to scale relative to each other. Like reference numerals designate corresponding similar parts.

FIG. 1 comprises FIGS. 1A and 1B and shows a cross-sectional side view (A) and a top view (B) on a semiconductor package of the present disclosure.

FIG. 2 comprises FIG. 2A to 2C and shows cross-sectional views for illustrating the process of inserting the semiconductor packages into bores of a heat sink.

FIG. 3 shows a cross-sectional representation of another example of the vertical portion of the fastening device.

### DESCRIPTION OF EMBODIMENTS

In the following detailed description, reference is made to the accompanying drawings, which form a part hereof, and in which is shown by way of illustration specific embodiments in which the disclosure may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled”elements, respectively.

Further, the word “over” used with regard to a part, element or material layer formed or located “over” a surface may be used herein to mean that the part, element or material layer be located (e.g. placed, formed, deposited, etc.) “indirectly on” the implied surface with one or more additional parts, elements or layers being arranged between the implied surface and the part, element or material layer. However, the word “over” used with regard to a part, element or material layer formed or located “over” a surface may, optionally, also have the specific meaning that the part, element or material layer be located (e.g. placed, formed, deposited, etc.) “directly on”, e.g. in direct contact with, the implied surface.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or multiple” unless specified otherwise or clear from context to be directed to a singular form. Also, at least one of A and B or the like generally means A or B or both A and B.

### DETAILED DESCRIPTION

The examples of a semiconductor package may use various types of transistor devices. The examples may also use horizontal or vertical transistor devices wherein those structures may be provided in a form in which all contact elements of the transistor device are provided on one of the main faces of the semiconductor die (horizontal transistor structures) or in a form in which at least one electrical contact element is arranged on a first main face of the semiconductor die and at least one other electrical contact element is arranged on a second main face opposite to the main face of the semiconductor die (vertical transistor structures) like, for example, MOS transistor structures or IGBT (Insulated Gate Bipolar Transistor) structures.

According to an embodiment of the semiconductor package, the semiconductor transistor die is a semiconductor power transistor die. Here, the term “power semiconductor transistor die” may refer to a semiconductor transistor die providing at least one of high voltage blocking or high current-carrying capabilities. A power semiconductor die may be configured for high currents having a maximum current value of a few Amperes, such as e.g. 10 A, 250 A, 600 A, 1000 A, or a maximum current value of up to or even exceeding 1000 A. Similarly, voltages associated with such current values may have values of a few Volts to a few tens or hundreds or even thousands of Volts.

The examples of a semiconductor package may comprise a housing at least partially enclosing the semiconductor dies. The housing may take the form of vertical walls surrounding the dies, and an optional lid enclosing the top of the housing. Alternatively, the housing may take the form of an encapsulant or encapsulating material having the semiconductor transistor die and the semiconductor driver die embedded therein. The encapsulating material can be any electrically insulating material like, for example, any kind of molding material, any kind of resin material, or any kind of epoxy material. The encapsulating material can also be a polymer material, a polyimide material, a thermoplast material, a silicone material, a ceramic material, and a glass material. The encapsulating material may also comprise any of the above-mentioned materials and further include filler materials embedded therein like, for example, thermally conductive increments like thermally conductive particles like, for example, made of AlO, BNi, AlNi, SiN, diamond, or any other thermally conductive particles.

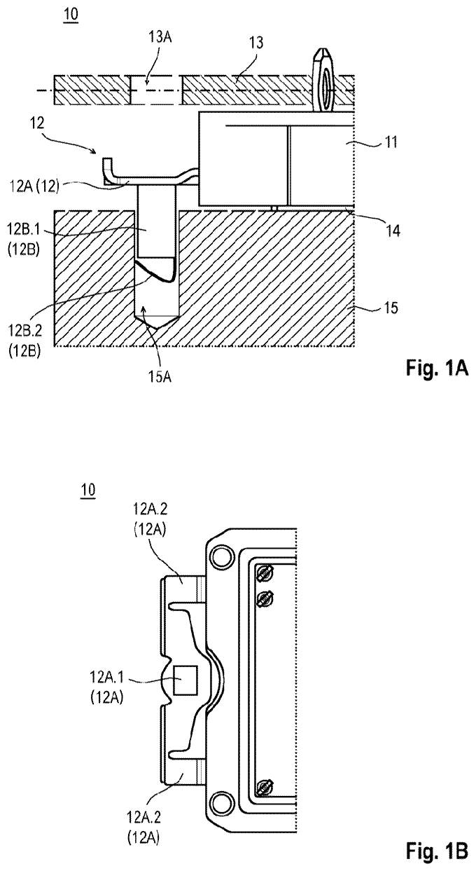

FIG. 1 comprises FIGS. 1A and 1B and shows a cross-sectional side view (A) and a top view (B) on a semiconductor package of the present disclosure.

The semiconductor package 10 shown in FIG. 1 comprises a semiconductor transistor die (not shown), in particular a semiconductor power transistor die, and a housing 11 at least partially enclosing the semiconductor transistor die. The semiconductor package 10 can in principle be of any kind. It can be in particular one which comprises a substrate (not shown) such as one or more of a direct copper bond (DCB), a direct aluminum bond, an aluminum metal braze (AMB), or an insulated metal substrate (IMS). The substrate is positioned in the housing 11 or on the bottom of the housing 11. When the housing 11 takes the form of walls and an optional lid, the substrate is fixed to the lower edges of the housing walls. When the housing 11 takes the form of an encapsulant, the substrate is typically embedded in a lower surface of the encapsulant. A DCB comprises as usual a center ceramic layer and two copper layers disposed on the upper and lower main faces of the ceramic layer. The semiconductor transistor die can be disposed, for example, on the upper copper layer of a DCB.

The semiconductor package 10 may further comprise a thermally conductive layer 14, in order to effectively transfer heat from the package (10) to the heat sink (15). The thermally conductive layer may be made of copper, disposed on the bottom surface of the housing 11 and in tight contact with the heat sink 15 in the fastened state. This thermally conductive layer 14 may also form the lower copper layer of the substrate. However, it is also contemplated that this layer could be formed of non-metallic materials, for example, thermal interface materials (TIM) which are thermally conductive but electrically insulating.

A printed circuit board (PCB) 13 may be fastened to electrical terminals 16 extending upward from the semiconductor package 10. The PCB 13 may comprise an electrical circuitry connected with the semiconductor transistor die via the package terminals, the electrical circuitry containing, for example, a semiconductor driver die for controlling the semiconductor transistor die and possibly passive device like, for example, resistors, capacitors, etc.

The semiconductor package 10 is to be mounted on a heat sink 15, in particular at a customer's side. To this end, the semiconductor package 10 comprises at least two fastening devices 12 only one of which is shown here. The two fastening devices 12 can be embedded in two opposing side walls of the housing 11.

Each one of the fastening devices 12 comprises an upper horizontal holding portion 12A which is fixed to the housing 11. In the embodiment shown here, the fixation is done by embedding a right end of the horizontal holding portion 12A in the housing 11. Each one of the fastening devices 12 further comprises a lower vertical portion 12B connected with the horizontal holding portion 12A.

In the embodiment of the semiconductor package 10 as shown in FIG. 1, the vertical portion 12B of the fastening device 12 comprises a vertical shaft 12B.1 and a spring 12B.2 attached to the vertical shaft 12B.1 at its external end, which spring 12B.2 is attached to a surface of the vertical shaft 12B.1 and then bent upwards so that it can hook with its external end on an inner wall of a bore 15A of the heat sink 15. Spring 12B.2 and shaft 12B.1 together form a wedge-shaped structure which facilitates insertion of the vertical portion 12B into the bore 15A of the heat sink 15.

The printed circuit board 13 comprises two through-holes 13A which, when the PCB 13 is fixed to the semiconductor package 10, are arranged directly above central sections of the horizontal portions 12A and the vertical portions 12B of the fastening devices 12. The through-holes 13A are used for inserting pins therethrough for pressing down the fastening devices 12.

The horizontal portion 12A of the fastening device 12 may further comprise a central portion 12A.1 and a resilient region 12A.2. The resilient region 12A.2 may take the form of two portions positioned on both sides of the central portion 12A.1. The resilient region 12A.2 exerts a restoring force at the end of the process of inserting of the vertical portion into the bore 15A of the heatsink 15.

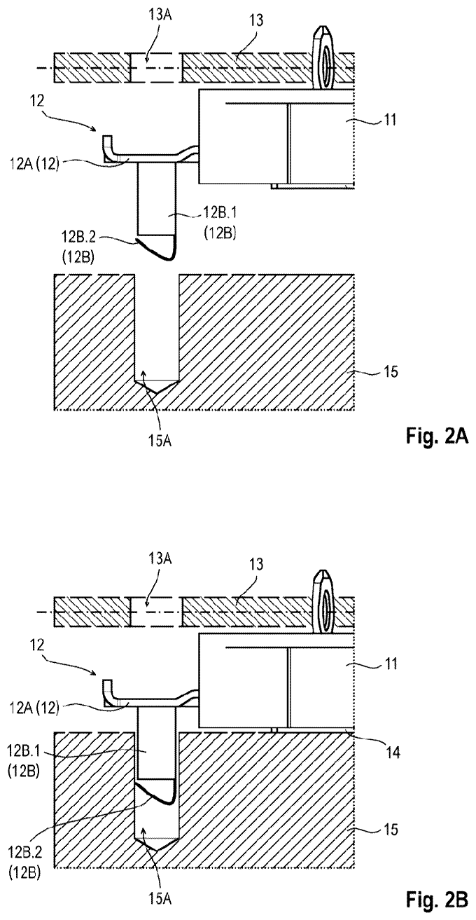

FIG. 2 comprises FIG. 2A to 2C and shows cross-sectional views for illustrating the process of inserting the semiconductor packages into bores of a heat sink.

FIG. 2A shows the situation before the vertical sections 12B of the two fastening devices 12 are inserted into holes 15A in the heat sink. The fastening devices 12 are aligned so that the vertical portions 12A are positioned above the holes 15A. Pins are then inserted through the through holes 13A of the PCB 13 and pressed downwards by exerting downward pressure on the pins. The pins are then used to press the central area 12A.1 of the horizontal portion 12 downwards and thus press the vertical portion 12B downwards into the bore 15A of the heat sink 15. These pins may form part of a single tool used to press both fastening devices 12 simultaneously.

FIG. 2B shows the situation in the middle of the process of inserting the vertical portions 12B into the bores 15A of the heatsink 15.

FIG. 2C shows the situation at the end of the process of inserting the vertical portions 12B into the bores 15A of the heatsink 15. The full insertion will cause the horizontal spring portion 12A to deflect downwards such that the portion 12A.2 sloped diagonally downwards and the inner spring portion 12A.1 lies in contact to and parallel with the upper planar surface of the heat sink 15. A restoring force is then provided by the resilient portion 12A.2 of the horizontal section 12A of the fastening device 12. This provides an upward force on the vertical section 12B, which causes the end of the spring 12B.2 to wedge into the inner wall of the bore 15A of the heat sink 15. For this purpose, the spring 12B.2 is preferably sharp-edged at its end. The portion of the spring 12B.2 opposite to this end is supported on the corresponding opposite inner wall of the bore 15A. Because the vertical portions 12B lock the horizontal section 12A in place against the heat sink 14, the resilient portion 12A.2 exerts a downward force on the semiconductor package so as to press the lower metallic surface 14 into contact with the heat sink 15.

The bores 15A can be blind holes with a defined diameter and tolerance which would be the easiest and cheapest way on the customer's side. Also the through holes 13A in the PCB 13 can be small so that the customer can use the additional space on the PCB 13 for other purposes.

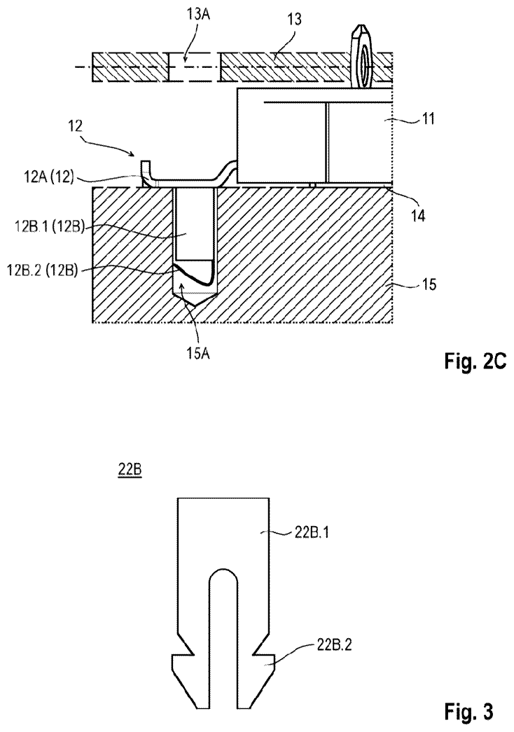

FIG. 3 shows a cross-sectional representation of another example of the vertical portion of the fastening device.

The lower vertical portion 22B as shown in FIG. 3 can be part of a fastening device which can otherwise be the same as that shown in FIG. 1, in particular having an upper holding portion 12A as shown in FIG. 1. Only the vertical portion is different from that of FIG. 1. The vertical portion of FIG. 2 comprises a vertical shaft 22B.1 and an external end 22B.2 which comprises the form of an expansion dowel. Here too, the lower outwardly projecting elements of the external end 22B.2 act so that they wedge into the inner walls of the bore 15A at the end of the process of pressing the vertical section 22B into the bore 15A. The vertical portion 22B can also be made of stainless steel.

In general, the metal claw can have different designs, but the working principle is always the same in that it should be designed to be easily inserted into a bore 15A but removable only with great difficulty if at all. While it is illustrated as a single integrally formed piece here, it could also be assembled from multiple sub-components. The claw is connected to the horizontal portion 12A which comprises an elastic spring element 12A.2. During insertion the claw is deflected by a vertical inner wall of the bore of the heatsink while the opposite side of the claw has to be supported by the other inner wall.

### EXAMPLES

In the following specific examples of the present disclosure are described.

Example 1 is a semiconductor package comprising a semiconductor transistor die, a housing at least partially enclosing the semiconductor transistor die, a lower thermally conductive planar surface, and at least two fastening devices for fastening the semiconductor package to a heat sink, each one of the fastening devices comprising an upper holding portion which is fixed to the housing and which comprises a resilient region, and a lower portion connected with the upper holding portion and configured to be inserted into the heat sink, the resilient region being configured to fix the lower portion in the heat sink and to press the lower thermally conductive planar surface against the heat sink.

Example 2 is the semiconductor package according to Example 1, wherein an external end of the lower portion is designed so that it can forced by the resilient region into a fixed engagement with the inner wall of a bore in the heat sink.

Example 3 is the semiconductor package according to Example 1 or 2, wherein the lower portion comprises a vertical shaft and a spring attached to the vertical shaft at its external end, which spring is bent upwards so that its external end can be forced by the resilient region into a fixed engagement with an inner wall of a bore of the heat sink.

Example 4 is the semiconductor package according to Example 1, wherein an external end of the lower portion has the form of an expansion dowel.

Example 5 is the semiconductor package according to any one of the preceding Examples, wherein the upper portion of the fastening device is partially embedded in the housing.

Example 6 is the semiconductor package according to any one of the preceding Examples, wherein the at least two fastening devices are fixed to two opposing side walls of the housing.

Example 7 is the semiconductor package according to any one of the preceding Examples, further comprising a substrate comprising upper and lower metallic layers, the semiconductor transistor die being attached to the upper metallic layer.

Example 8 is the semiconductor package according to Example 7, wherein the lower metallic layer forms the thermally conductive planar surface.

Example 9 is an assembly comprising the semiconductor package according to any one of the preceding Examples, and a printed circuit board connected to an electrical terminal extending upward from the semiconductor package.

Example 10 is the assembly according to Example 9, wherein the printed circuit board comprises two through-holes which are arranged directly above central sections of the horizontal portions and the vertical portions of the fastening devices.

Example 11 is a method for mounting an assembly to a heat sink, the assembly comprising a printed circuit board and a semiconductor package, the package further comprising a semiconductor die, a housing at least partially enclosing the semiconductor die, a lower thermally conductive surface and at least two fastening devices, each of the fastening devices further comprising a resilient region, the method comprising: positioning the assembly on the heat sink such that the lower thermally conductive surface engages the heat sink and each of the at least two fastening devices are positioned above a corresponding bore in the heat sink, pressing each of the fastening devices downward against a resistive force exerted by the resilient regions such that lower portions of the fastening devices are inserted into the bores, and releasing the force upon the fastening devices such that the resilient regions force the lower portions into fixed engagement with the bores and force the lower thermally conductive surface against the heat sink.

Example 12 is mounting method of Example 11, wherein the at least two fastening devices are pressed downward simultaneously.

Example 13 is the mounting method of Example 11 or 12, wherein each of the at least two fastening devices are pressed down upon by a tool inserted through a corresponding hole in the printed circuit board.

Example 14 is the mounting method of any one of Examples 11 to 13, wherein the at least two fastening devices are each pressed down upon by a corresponding pin of a single tool

In addition, while a particular feature or aspect of an embodiment of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Furthermore, it should be understood that embodiments of the disclosure may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. A semiconductor package, comprising a semiconductor transistor die;
a housing at least partially enclosing the semiconductor transistor die;
a lower thermally conductive planar surface; and
at least two fastening devices for fastening the semiconductor package to a heat sink, each one of the fastening devices comprising
an upper holding portion which is fixed to the housing and which comprises a resilient region; and
a lower portion connected with the upper holding portion and configured to be inserted into the heat sink, the resilient region being configured to fix the lower portion in the heat sink and to press the lower thermally conductive planar surface against the heat sink.

2. The semiconductor package according to claim 1, wherein an external end of the lower portion is designed so that it can forced by the resilient region into a fixed engagement with the inner wall of a bore in the heat sink.

3. The semiconductor package according to claim 1, wherein the lower portion comprises a vertical shaft and a spring attached to the vertical shaft at its external end, which spring is bent upwards so that its external end can be forced by the resilient region (12A.2) into a fixed engagement with an inner wall of a bore of the heat sink.

4. The semiconductor package according to claim 1, wherein an external end of the lower portion (12B) has the form of an expansion dowel.

5. The semiconductor package according to claim 1, wherein the upper portion of the fastening device is partially embedded in the housing.

6. The semiconductor package according to claim 1, wherein the at least two fastening devices are fixed to two opposing side walls of the housing.

7. The semiconductor package according to claim 1, further comprising:
a substrate comprising upper and lower metallic layers, the semiconductor transistor die being attached to the upper metallic layer.

8. The semiconductor package according to claim 7, wherein the lower metallic layer forms the thermally conductive planar surface.

9. The semiconductor package according to claim 1, further comprising:
a printed circuit board connected to an electrical terminal extending upward from the semiconductor package.

10. The assembly according to claim 9, wherein the printed circuit board comprises two through-holes which are arranged directly above central sections of the horizontal portions and the vertical portions of the fastening devices.

11. A method for mounting an assembly to a heat sink, the assembly comprising a printed circuit board and a semiconductor package, the package further comprising a semiconductor die, a housing at least partially enclosing the semiconductor die, a lower thermally conductive surface and at least two fastening devices, each of the fastening devices further comprising a resilient region, the method comprising:
positioning the assembly on the heat sink such that the lower thermally conductive surface engages the heat sink and each of the at least two fastening devices are positioned above a corresponding bore in the heat sink;
pressing each of the fastening devices downward against a resistive force exerted by the resilient regions such that lower portions of the fastening devices are inserted into the bores; and
releasing the force upon the fastening devices such that the resilient regions force the lower portions into fixed engagement with the bores and force the lower thermally conductive surface against the heat sink.

12. The mounting method of claim 11, wherein the at least two fastening devices are pressed downward simultaneously.

13. The mounting method of claim 11, wherein each of the at least two fastening devices are pressed down upon by a tool inserted through a corresponding hole in the printed circuit board.

14. The mounting method of claim 11, wherein the at least two fastening devices are each pressed down upon by a corresponding pin of a single tool.
